(19) United States
(12) Patent Application Publication
(10) Pub. No.: US 2014/0162456 A1
(43) Pub. Date: Jun. 12, 2014

(54) METHOD FOR POLISHING SILICON WAFER AND POLISHING AGENT

(71) Applicants: Shigeru Oba, Nishishirakawa (JP); Takao Kawamata, Nishishirakawa (JP)

(72) Inventors: Shigeru Oba, Nishishirakawa (JP); Takao Kawamata, Nishishirakawa (JP)

(73) Assignee: SHIN-ETSU HANDOTAI CO., LTD., Tokyo (JP)

(21) Appl. No.: 14/236,858

(22) PCT Filed: Aug. 13, 2012
(86) PCT No.: PCT/JP2012/005135

§ 371 Date: Feb. 3, 2014

(30) Foreign Application Priority Data
Sep. 1, 2011 (JP) 2011-190916

(51) Int. Cl. H01L 21/02; C09G 1/02

(52) U.S. Cl. CPC H01L 21/02024; C09G 1/02
USPC 438/693; 252/79.5

(57) ABSTRACT

The present invention is directed to a method for polishing a silicon wafer, the method comprising: polishing the silicon wafer by bringing the silicon wafer into sliding contact with a polishing pad attached to a turn table while supplying a polishing agent stored in a tank to the polishing pad; and circulating the polishing agent to recover the supplied polishing agent in the tank, wherein the silicon wafer is polished while adjusting a concentration of silicate ions contained in the polishing agent in the tank to be within a predetermined range. The present invention provides a polishing agent having a high polishing rate that enables the polishing rate to be kept constant among polishing batches, and a method for polishing a silicon wafer accurately with a target polishing stock removal or a target finishing thickness by using the polishing agent.

### TECHNICAL FIELD

The present invention relates to a method for polishing a silicon wafer by bringing the silicon wafer into sliding contact with a polishing pad while supplying a polishing agent, and to the polishing agent.

### BACKGROUND ART

In general, a method for producing a silicon wafer includes a slicing process of slicing a silicon ingot to obtain a thin disk-shaped wafer, a chamfering process of chamfering the outer region of the wafer obtained by the slicing process to prevent a fracture and a chip in the wafer, a lapping process of flattening the chamfered wafer, an etching process of removing mechanical damage remaining in the chamfered and lapped wafer, a polishing (polishing) process of mirror-polishing the front surface of the etched wafer, and a cleaning process of cleaning the polished wafer to remove a polishing agent and foreign substances attached to the wafer.

Those described above are only main processes, and a heat treatment process, a surface grinding process, and the like may be further added or the sequence of processes may be changed. Moreover, the same process maybe performed more than once. Then, an inspection or the like is performed, and the silicon wafer is sent to a device production process and an insulator film and a metal wiring line are formed on the front surface of the silicon wafer, whereby a device such as a memory is produced.

The above-described polishing process is a process that polishes the front surface of the silicon wafer to a mirror-smooth state by bringing the silicon wafer into sliding contact with the polishing pad while supplying the polishing agent, and mirror-polishing the silicon wafer to have a high degree of flatness and an improvement in polishing rate are sought after. As the polishing agent used in this polishing process, a polishing agent containing mainly alumina or colloidal silica (SiO₂) is often used. In particular, a polishing agent in the form of a suspension (slurry) obtained by diluting alumina or colloidal silica with water and adding an alkali thereto is used.

Here, as a method for improving the polishing rate, ingenuity is sometimes used to improve the polishing agent used for polishing. For example, as the above-described silica-based polishing agent, a polishing agent with a particle diameter of about 10 to 150 nm is used. The polishing performance is enhanced with an increase in the grain size of silica contained in the polishing agent. However, the larger the particle diameter becomes, the more polishing damage or the like occurs in the wafer surface.

Moreover, as another method for improving the polishing rate, there is a method by which a pH adjuster is added to a polishing agent to keep the pH constant (refer to, for example, Patent Document 1). Here, as an additive, sodium hydroxide, potassium hydroxide, sodium carbonate, potassium carbonate, sodium bicarbonate, potassium bicarbonate, and the like are used.

### CITATION LIST

### Patent Literature

Patent Document 1: Japanese Unexamined Patent Application Publication No. 2000-263441

### SUMMARY OF INVENTION

### Technical Problem

In general, it is known that, when this pH adjuster is added to the polishing agent, the polishing rate is improved if the pH is kept at 10.5 or more, but, if such a high pH state is maintained, hazardous metal impurities such as nickel and copper are easily introduced into the silicon wafer at the time of fabrication of a device. Therefore, in the past, a polishing agent has been used in a state in which the pH of the polishing agent is kept at about 10.5.

Here, the silica-based polishing agent used in polishing of the silicon wafer contains water, silica, and an alkali and causes a reaction expressed by the following formula during polishing.

Si+2OH⁻+H₂O→SiO₃²⁻+2H₂↑

In the past, based on this formula, a polishing rate k has been considered as follows. Si is usually a solid and there is a surplus of H₂O. The polishing agent contains silica and is regarded as a polymer of SiO₃²⁻, and, if there is also a surplus thereof, the polishing rate k can be expressed as follows.

k∝C×[H₂O][OH⁻]²/[SiO₃²⁻]→k∝C′×[OH⁻²

As described above, only a case in which the concentration of hydroxide ions is higher than the concentration of silicate ions SiO₃²⁻ which are by-products is considered, and an emphasis is placed on control of [OH⁻]. That is, the pH of the polishing agent is measured, and, if the measured pH is below a predetermined value (for example, 10.5), an adjustment by which a pH adjuster such as NaOH, KOH, Na₂CO₃, or K₂CO₃ is added is made.

However, when the silicon wafer is polished by using a polishing agent adjusted by such an existing method for keeping the pH at a predetermined value, although the polishing rate can be improved, the polishing rate varies among polishing batches, and an error of about 1 to a few μm occurs with respect to a target thickness even when each batch is polished for the same polishing time.

To control a higher-precision polishing stock removal and finished thickness, it is necessary to adjust the state of a polishing agent so that each batch polishing rate becomes almost constant and set the polishing time accurately, and, if the polishing rate does not become constant as described above, an accurate polishing time cannot be set.

In recent years, the tolerance of a stock removal has become about 0.1 μm or less as the polished silicon wafer has been required to have a higher degree of flatness, but the existing method cannot meet this requirement. Moreover, with the existing method, the polishing rate is greatly decreased with a progress of polishing batch processing, and the number of batch processing that can be used is short.

The present invention has been made in view of the above problems, and an object thereof is to provide a polishing agent having a high polishing rate that enables the polishing rate to be kept constant among polishing batches, and a method for polishing a silicon wafer accurately with a target polishing stock removal or a target finishing thickness with the polishing agent.

### Solution to Problem

To achieve the above-described object, the present invention provides a method for polishing a silicon wafer, the method comprising: polishing the silicon wafer by bringing the silicon wafer into sliding contact with a polishing pad attached to a turn table while supplying a polishing agent stored in a tank to the polishing pad; and circulating the polishing agent to recover the supplied polishing agent in the tank, wherein the silicon wafer is polished while adjusting a concentration of silicate ions contained in the polishing agent in the tank to be within a predetermined range.

The method can maintain a high polishing rate and a constant polishing rate among polishing batches, thereby enabling an accurate polishing time to be set. The polishing stock removal or the finishing thickness can therefore be accurately controlled to be the target value.

The method preferably includes adding a new polishing agent to the tank in the same amount as that of a part of the supplied polishing agent that is not recovered in the tank, and the concentration of silicate ions that is reduced because of the part of the polishing agent not being recovered in the tank is preferably adjusted to be within the predetermined range by adding alkali to the polishing agent in the tank during polishing of the silicon wafer to generate the silicate ions by a reaction between the alkali and the silicon wafer.

In this manner, the concentration of silicate ions, reduced because of the part of the polishing agent not being recovered in the tank, can be readily adjusted to be within the predetermined range. In addition, generating the silicate ions by the reaction between the alkali and the silicon wafer suppresses an increase in cost. The polishing rate can be controlled by adjusting the amount of the polishing agent that is not recovered in the tank and the amount of the alkali that is added to the polishing agent in the tank.

The concentration of silicate ions is preferably adjusted to be within the range of 1.0 to 4.6 g/L.

Such an adjustment ensures a constant, high polishing rate among polishing batches.

The alkali is preferably added in a constant amount per predetermined time to the polishing agent in the tank during polishing of the silicon wafer.

In this manner, the concentration of silicate ions can readily and surely be adjusted to be within the predetermined range, and prevented from becoming unstable due to a temporary decrease in concentration of silicate ions by the added alkali.

The alkali added during polishing of the silicon wafer is preferably at least one of sodium carbonate, potassium carbonate, sodium bicarbonate, potassium bicarbonate, sodium hydroxide, and potassium hydroxide.

The inventive method for polishing a silicon wafer of the present invention can apply various alkalis.

Furthermore, the present invention provides a polishing agent for use to be supplied to a polishing pad attached to a turn table when a silicon wafer is polished by being brought into sliding contact with the polishing pad, the polishing agent containing water, silica, alkali, and silicate ions, wherein a concentration of silicate ions is adjusted to be within a range of 1.0 to 4.6 g/L.

Polishing a silicon wafer with such a polishing agent can maintain a high polishing rate and a constant polishing rate among polishing batches, thereby enabling an accurate polishing time to be set. The polishing stock removal or the finishing thickness can therefore be accurately controlled to be the target value.

### Advantageous Effects of Invention

The method for polishing a silicon wafer of the present invention involves polishing a silicon wafer while adjusting the concentration of silicate ions contained in the polishing agent in the tank to be within a predetermined range. The method can maintain a high polishing rate and a constant polishing rate among polishing batches, thereby enabling an accurate polishing time to be set, and the polishing stock removal or the finishing thickness to be accurately controlled so as to be the target value. The method can also suppress variation of the polishing rate over a long period of time, thereby enabling a longer target life of the polishing agent to be set.

### BRIEF DESCRIPTION OF DRAWINGS

FIG. 1A is a schematic cross-sectional view of an example of a double-side polishing apparatus usable for a method for polishing a silicon wafer of the present invention;

FIG. 1B is a top internal-structure view of the double-side polishing apparatus illustrated in FIG. 1A;

FIG. 2 shows the results of an example; and

FIG. 3 shows the results of a comparative example.

### DESCRIPTION OF EMBODIMENTS

Hereinafter, embodiments of the present invention will be described, but the present invention is not limited thereto.

A conventional method for polishing a silicon wafer involves controlling the pH value of a polishing agent and polishing the wafer while holding the pH value at about 10.5, for example, to improve the polishing rate. In such a method, however, the polishing rate varies and does not become constant among polishing batches, although the polishing rate increases as described above. The present inventors found that the polishing rate is hard to increase for a while, in particular, right after a newly diluted polishing agent is prepared.

The present inventors accordingly conducted intensive studies to solve such problems, and found that the concentration of silicate ions, which is not conventionally taken into consideration, is one of factors in change in the polishing rate, and that the reason why the polishing rate is hard to increase for a while, in particular, right after a newly diluted polishing agent is prepared is that the concentration of silicate ions has not been increased to an adequate level even when the pH is increased to an adequately high level. The present inventors also found that a constant, high polishing rate can be stably kept by adjusting the concentration of silicate ions within a predetermined range, thereby brought the present invention to completion.

The polishing agent of the present invention is supplied to a polishing pad attached to a turn table when a silicon wafer is polished by bringing the wafer into sliding contact with the polishing pad.

The method for polishing a silicon wafer of the present invention involves polishing the silicon wafer by bringing the wafer into sliding contact with a polishing pad attached to a turn table while supplying the inventive polishing agent stored in a tank to the polishing pad and circulating the polishing agent to recover the supplied polishing agent in the tank.

Here, the present invention can be applied to both double-side polishing by which both sides of a silicon wafer are polished at the same time and single-side polishing by which one side of a silicon wafer is polished.

The polishing agent of the present invention will now be described.

The polishing agent of the present invention contains water, silica, alkali, and silicate ions. The polishing agent may be a suspension containing silicate ions, which is obtained by diluting colloidal silica, for example, having a particle diameter of about 10 to 150 nm with water and adding alkali thereto. Here, the added alkali may be at least one of sodium carbonate, potassium carbonate, sodium bicarbonate, potassium bicarbonate, sodium hydroxide, and potassium hydroxide, for example. The polishing agent may contain a chelating agent to prevent metal impurity contamination.

The concentration of silicate ions in the polishing agent of the present invention is adjusted to be within a range of 1.0 to 4.6 g/L. The silicate ions include silicate ions introduced from the outside of the system and silicate ions generated by the reaction between a silicon wafer and the alkali during polishing of the silicon wafer. In other words, the concentration of silicate ions is adjusted to be within the above-described range during polishing of the silicon wafer.

Polishing a silicon wafer with such a polishing agent can maintain a high polishing rate and a constant polishing rate among polishing batches, thereby enabling an accurate polishing time to be set. The polishing stock removal or the finishing thickness can therefore be accurately controlled to be the target value.

Next, the method for polishing a silicon wafer of the present invention will be described. The method described here, by way of example, uses a double-side polishing apparatus capable of polishing both surfaces of silicon wafers at the same time. The present invention, however, is not limited to this example. The method can also be performed by using a double-side polishing apparatus of a single-wafer-processing type that polishes both sides of a silicon wafer at the same time, or a single-side polishing apparatus that polishes one side of a silicon wafer, for example.

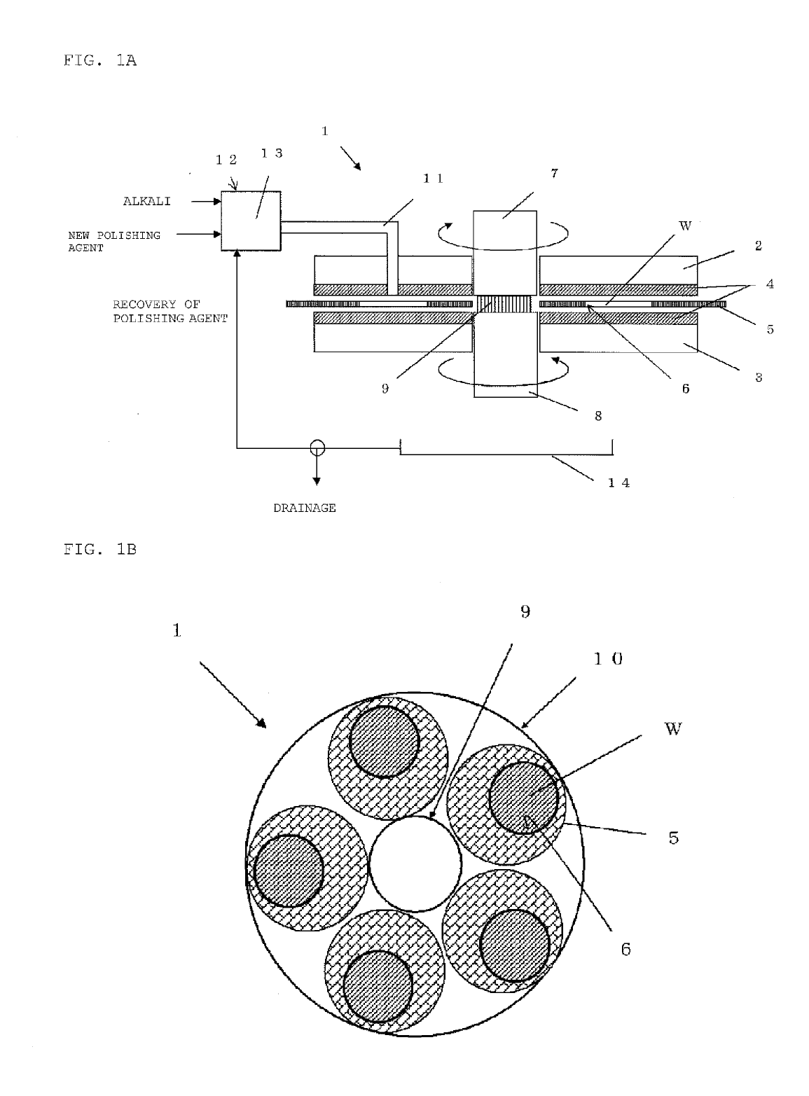

As depicted in FIG. 1A and FIG. 1B, a double-side polishing apparatus 1 includes an upper turn table 2 and a lower turn table 3 that are provided so as to face each other vertically, and a polishing pad 4 is attached to each of the upper and lower turn tables 2 and 3. At the center of the upper and lower turn tables 2 and 3, a sun gear 9 is provided, and an internal gear 10 is provided at the outer edge of these tables. A holding hole 6 for holding a silicon wafer W is provided in a carrier 5, and a plurality of the carriers 5 are interposed between the upper and lower turn tables 2 and 3.

Outer circumferential gears of the carriers 5 engage the respective teeth of the sun gear 9 and the internal gear 10. As the upper turn table 2 and the lower turn table 3 are rotated at predetermined rotational speeds by an upper rotating shaft 7 and a lower rotating shaft 8, respectively, the carriers 5 revolve around the sun gear 9 while rotating about their own axes. Both surfaces of the silicon wafers W held in the holding holes 6 of the carriers 5 are brought into sliding contact with the polishing pads 4 and polished at the same time. At this time, a polishing agent 13 in a tank 12 is supplied to the polishing pads 4 through a nozzle 11.

The supplied polishing agent 13 has the same composition as that of the above polishing agent of the present invention. A part of the supplied polishing agent 13 flows down on a turn table receiver 14, then is collected, and recovered in the tank 12, while the other part of the polishing agent 13, such as a spattered part and a discharged part as a mist during polishing, is unable to be recovered. The recovered polishing agent is used for subsequent polishing. The polishing agent 13 thus circulates between the tank 12 and the double-side polishing apparatus 1.

The inventive method for polishing a silicon wafer involves polishing the silicon wafer W while adjusting the concentration of silicate ions contained in the polishing agent 13 in the tank 12 to be within a predetermined range to be within a predetermined range. The present invention thus stabilizes the polishing rate by adjusting the concentration of silicate ions in the polishing agent, which is not taken into consideration in the past.

The present invention does not particularly limit how the concentration of silicate ions is adjusted, and an exemplary method of adjusting the concentration of silicate ions is given as follows: The concentration is decreased by discharging a part of the supplied polishing agent and adding a new polishing agent containing no silicate ion or containing silicate ions whose concentration is lower than the target concentration, while the concentration is increased by adding silicate ions directly. Alternatively, the concentration may be increased by adding alkali and generating silicate ions due to the reaction between the added alkali and a silicon wafer, as described later.

Such a method can maintain a high polishing rate and a constant polishing rate among polishing batches, thereby enabling an accurate polishing time to be set, and the polishing stock removal or the finishing thickness to be accurately controlled so as to be the target value. The method can also suppress variation of the polishing rate over a long period of time, thereby enabling a longer target life of the polishing agent to be set. Furthermore, providing a coefficient according to the resistivity of silicon wafers allows the polishing rate to be predicted in advance in every polishing of a silicon wafer having different resistivity.

The polished silicon wafer exposes metal silicon on its surfaces. If the surfaces are exposed to air with the polishing agent being adhered thereto, the surface may be roughened due to a nonuniform reaction between the metal silicon and the alkali. Accordingly, pure water or a surface-active agent is generally poured onto the surfaces of the silicon wafer to remove the alkali from the surfaces of the silicon wafer immediately after the completion of polishing. After the polishing is completed and before next polishing (a next batch) is performed, cleaning water is generally poured onto the polishing pads and the polishing pad is scrubbed with a brush and so on to remove foreign substances, by-products, agglomerate of the polishing agent from the polishing pad.

The part of the unrecoverable polishing agent is mixed with the cleaning water or the surface-active agent used in this manner and remains in a section between the turn table receiver and piping. The polishing agent in this mixture cannot be recovered to prevent the cleaning water or the surface-active agent from entering the polishing agent in the tank, and is accordingly discharged. A separator provided between the piping and the tank allows the polishing agent between to be recovered and to be discharged. The polishing agent in the tank decreases since a part of the supplied polishing agent, such as the above discharged part and the above spattered part during polishing, cannot not be recovered in the tank, and to compensate the decrease, a new polishing agent is added to the tank in the same amount as the decreased polishing agent.

The new polishing agent is added in such a way that the proportion of silica, water, and so on in the polishing agent 13 in the tank is not changed.

The concentration of silicate ions, reduced because of the part of the polishing agent not being recovered in the tank, is adjusted to be within a predetermined range by adding alkali to the polishing agent in the tank during polishing of the silicon wafer to generate the silicate ions by the reaction between the alkali and the silicon wafer.

At this time, the amount of the polishing agent to be discharged can be adjusted by switching of the separator in accordance with the time elapsed after the start of polishing. The amount of the unrecoverable polishing agent, such as the spattered polishing agent, is substantially constant among the batches. Since the amount of the polishing agent that cannot be recovered in the tank is constant among the batches, the concentration of silicate ions can readily be adjusted by adjusting the amount of alkali to be added to the polishing agent in the tank. Moreover, since the silicate ions are generated by the reaction between the alkali and the silicon wafer, it is possible to suppress an increase in cost.

Furthermore, a fine adjustment of the concentration of silicate ions can be made within a predetermined range by adjusting the balance between the amount of the part of the polishing agent that is not recovered in the tank and the amount of alkali that is added to the polishing agent in the tank, whereby the polishing rate can also be adjusted.

The amount of alkali that is added to adjust the concentration of silicate ions to be within a predetermined range and the amount of the discharged polishing agent can be determined by performing simulations.

An example of the simulations is described below.

As listed in Table 1, when a stock removal is 16 μm, a polishing weight is 13.18 g (the volume of a portion to be polished×the Si density×the number of wafers) and the amount of SiO₃²⁻ generated by the reaction is 28.23 g (the molecular weight×the polishing weight), under simulation conditions of polishing five silicon wafers each having a diameter of 300 mm at the same time. The replacement rate indicates the proportion of the polishing agent that is recovered in the tank. The residual rate indicates the proportion of silicate ions remaining in the polishing agent to the silicate ions generated by the reaction between the silicon wafer and the alkali. Silicate ions that do not remain in the polishing agent are discharged to the outside of the system through the recoverable polishing agent. The residual rate is accordingly determined on the basis of the amount of the discharged polishing agent and the amount of the added alkali during polishing. The concentration of silicate ions after an arbitrary batch can be simulated by using the residual rate as a parameter.

TABLE 1

| Si density | 2.33 | g/cm³ |
|---|---|---|
| Wafer radius | 15 | cm |
| Stock removal | 16 | μm |
| The number of wafers | 5 | |
| Polishing weight | 13.18 | g |
| The amount of generated SiO₃²⁻ | 28.23 | g |
| residual rate | 39.6% | |
| Replacement rate | 87.1% | |
| The amount of added polishing agent | 0.8 | L |
| Initial concentration of silicate ions | 0.23 | g/L |

The concentration after polishing can be specifically calculated by adding increased silicate ions, which is calculated by the amount of generated SiO₃²⁻×the residual rate, to the initial concentration.

The results of the simulation under the conditions of Table 1 are given in Table 2. As listed in Table 2, the concentration of silicate ions increases as the polishing batch is repeated, and is kept substantially constant after 20 batches. Simulating the concentration so as to fall within a predetermined range can provide the amount of a polishing agent to be discharged and the amount of alkali to be added in each batch.

TABLE 2

| The number of batches | Concentration |
|---|---|
| 0 | 0.23 |
| 5 | 1.6 |
| 10 | 3.0 |
| 20 | 4.6 |
| 50 | 4.6 |
| 100 | 4.6 |

The concentration of silicate ions is preferably adjusted to be within the range of 1.0 to 4.6 g/L.

Such an adjustment ensures a constant, high polishing rate among polishing batches.

The alkali is preferably added in a constant amount per predetermined time to the polishing agent in the tank during polishing of the silicon wafer. The constant amount per predetermined time may be appropriately determined according to a polishing apparatus to be used, or the volume of a tank.

Such an adjustment enables the concentration of silicate ions to be surely adjusted within the predetermined range and to be prevented from becoming unstable due to a temporary decrease in concentration of silicate ions by the added alkali.

Alternatively, the total amount of the alkali that is needed may be added at once during polishing, before polishing, or after polishing, when the total amount needed is small and particularly a polishing cycle is sufficiently short.

The alkali that is added during polishing of the silicon wafer may be at least one of sodium carbonate, potassium carbonate, sodium bicarbonate, potassium bicarbonate, sodium hydroxide, and potassium hydroxide. The present invention can apply various alkalis.

A newly created polishing agent needs to increase silicate ions contained therein by adding silicate ions or polishing a dummy silicon wafer while adding alkali, for example and to adjust the concentration of silicate ions to be within a predetermined range (for example, during the period between 0 to 15 batches in the above simulation). After this adjustment, polishing of silicon wafers are repeated while the concentration of silicate ions is adjusted to be within a predetermined range according to the inventive method for polishing a silicon wafer so that the polishing rate can be stably kept constant over a long period of time.

Examples of a method for readily evaluating the concentration of silicate ions in a polishing agent include the specific gravity, the electrical conductivity, the turbidity of the polishing agent, for example. It can be understood that when they are constant, the concentration of silicate ions is also constant.

The concentration of silicate ions that dissolve in the polishing agent circulating depends on the polishing stock removal, and increases with an increase in required stock removal, when the volume of the tank and the number of silicon wafers that are set (the number of silicon wafers that are polished at the same time) are constant. The upper limit of the concentration is preferably 4.6 g/L for polishing with a large stock removal such as double-side polishing, as illustrated in the drawing.

The dissolving silicate ions are not expected to increase too much for polishing with a negligible polishing stock removal such as finish polishing. In this case, the concentration of the dissolving silicate ions depends on the concentration of silicate ions contained in an undiluted slurry, and is preferably 1.0 g/L or more to expect a high polishing rate.

### EXAMPLES

Hereinafter, the present invention will be described more specifically with an example and a comparative example of the present invention, but the present invention is not limited to these examples.

### Example

By using the double-side polishing apparatus capable of polishing five silicon wafers at the same time, as depicted in FIG. 1, polishing of silicon wafers with a diameter of 300 mm was repeated in a batch manner with the concentration of silicate ions in the polishing agent being adjusted to be 4.6 g/L, according to the method for polishing a silicon wafer of the present invention. The number of wafers to be polished per batch was five. Etched silicon wafers having a thickness of about 793±2 μm were polished under a polishing pressure of 200 g/cm² for such a polishing time that the thickness of the wafers was reduced to 777 μm, i.e., the stock removal became about 16 μm. The polishing stock removal was examined by measuring the thickness of the polished silicon wafers, and the polishing rate was calculated from the polishing stock removal and the polishing time and evaluated.

First, the polishing agent of the present invention was created in the following manner.

About 0.6 weight % of colloidal silica with a primary particle size of 35 nm and about 0.075 weight % of KOH as alkali were put in a 70-L capacity tank and agitated to obtain a base polishing agent. Dummy silicon wafers were then polished while supplying the base polishing agent and adding 5% KOH to adjust the concentration of silicate ions in the polishing agent to be 4.6 g/L.

The polishing of silicon wafers were repeated with the polishing agent of the present invention created in this manner to evaluate the polishing rate of each polishing batch. At this time, the concentration of silicate ions in the polishing agent was adjusted to be 4.6 g/L in such a manner that a 9-L polishing agent of the supplied polishing agent was discharged and a 9-L new polishing agent was added after each polishing, and 5% KOH was added in an amount of 3 ml every 2 minutes to the polishing agent in the tank during each polishing.

The concentration of silicate ions after polishing was measured by a molybdenum yellow method.

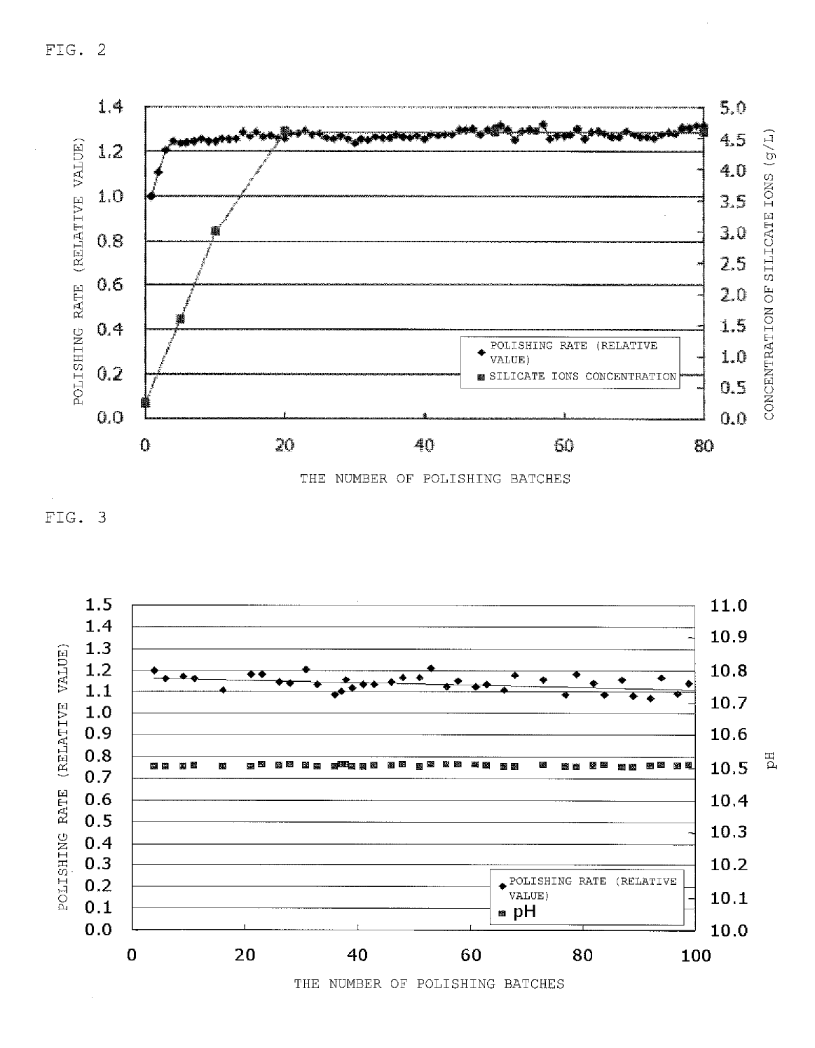

The results are shown in FIG. 2. The polishing rates in FIG. 2 are expressed by relative values obtained when the polishing rate at the time of polishing the dummy wafers to create the polishing agent is converted into 1. As shown in FIG. 2, the method of polishing the wafers while adjusting the concentration of silicate ions to be 4.6 g/L was able to keep the polishing rate substantially constant among the batches and also to hold the polishing rate at a high level, which was equal level as compared to the results of Comparative Example shown in FIG. 3. Moreover, it was revealed that the target polishing stock removal was able to be achieved stably.

It was thus confirmed that the method for polishing a silicon wafer and the polishing agent of the present invention can keep a high polishing rate constant among polishing batches, thereby controlling the polishing stock removal or the finishing thickness to be the target value accurately.

### Comparative Example

Silicon wafers were polished under the same conditions as those of Example except that the pH of a polishing agent was kept constant while the concentration of silicate ions was not adjusted according to a conventional polishing method, and the polishing rate was evaluated as with Example.

The results are shown in FIG. 3. The polishing rates in FIG. 3 are expressed by relative values with respect to the polishing rates in Example. As shown in FIG. 3, although the pH of the polishing agent was kept constant, the polishing rate varied more than that in Example. The variations in the polishing rate caused variations in the polishing stock removal.

It is to be noted that the present invention is not limited to the foregoing embodiment. The embodiment is just an exemplification, and any examples that have substantially the same feature and demonstrate the same functions and effects as those in the technical concept described in claims of the present invention are included in the technical scope of the present invention.

1-6. (canceled)

7. A method for polishing a silicon wafer, the method comprising:
polishing the silicon wafer by bringing the silicon wafer into sliding contact with a polishing pad attached to a turn table while supplying a polishing agent stored in a tank to the polishing pad; and
circulating the polishing agent to recover the supplied polishing agent in the tank, wherein
the silicon wafer is polished while adjusting a concentration of silicate ions contained in the polishing agent in the tank to be within a predetermined range.

8. The method for polishing a silicon wafer according to claim 7, further comprising
adding a new polishing agent to the tank in the same amount as that of a part of the supplied polishing agent that is not recovered in the tank, wherein
the concentration of silicate ions that is reduced because of the part of the polishing agent not being recovered in the tank is adjusted to be within the predetermined range by adding alkali to the polishing agent in the tank during polishing of the silicon wafer to generate the silicate ions by a reaction between the alkali and the silicon wafer.

9. The method for polishing a silicon wafer according to claim 7, wherein the concentration of silicate ions is adjusted to be within a range of 1.0 to 4.6 g/L.

10. The method for polishing a silicon wafer according to claim 8, wherein the concentration of silicate ions is adjusted to be within a range of 1.0 to 4.6 g/L.

11. The method for polishing a silicon wafer according to claim 8, wherein the alkali is added in a constant amount per predetermined time to the polishing agent in the tank during polishing of the silicon wafer.

12. The method for polishing a silicon wafer according to claim 9, wherein the alkali is added in a constant amount per predetermined time to the polishing agent in the tank during polishing of the silicon wafer.

13. The method for polishing a silicon wafer according to claim 10, wherein the alkali is added in a constant amount per predetermined time to the polishing agent in the tank during polishing of the silicon wafer.

14. The method for polishing a silicon wafer according to claim 8, wherein
the alkali added during polishing of the silicon wafer is at least one of sodium carbonate, potassium carbonate, sodium bicarbonate, potassium bicarbonate, sodium hydroxide, and potassium hydroxide.

15. The method for polishing a silicon wafer according to claim 9, wherein
the alkali added during polishing of the silicon wafer is at least one of sodium carbonate, potassium carbonate, sodium bicarbonate, potassium bicarbonate, sodium hydroxide, and potassium hydroxide.

16. The method for polishing a silicon wafer according to claim 10, wherein
the alkali added during polishing of the silicon wafer is at least one of sodium carbonate, potassium carbonate, sodium bicarbonate, potassium bicarbonate, sodium hydroxide, and potassium hydroxide.

17. The method for polishing a silicon wafer according to claim 11, wherein
the alkali added during polishing of the silicon wafer is at least one of sodium carbonate, potassium carbonate, sodium bicarbonate, potassium bicarbonate, sodium hydroxide, and potassium hydroxide.

18. The method for polishing a silicon wafer according to claim 12, wherein
the alkali added during polishing of the silicon wafer is at least one of sodium carbonate, potassium carbonate, sodium bicarbonate, potassium bicarbonate, sodium hydroxide, and potassium hydroxide.

19. The method for polishing a silicon wafer according to claim 13, wherein
the alkali added during polishing of the silicon wafer is at least one of sodium carbonate, potassium carbonate, sodium bicarbonate, potassium bicarbonate, sodium hydroxide, and potassium hydroxide.

20. A polishing agent for use to be supplied to a polishing pad attached to a turn table when a silicon wafer is polished by being brought into sliding contact with the polishing pad,
the polishing agent containing water, silica, alkali, and silicate ions, wherein a concentration of silicate ions is adjusted to be within a range of 1.0 to 4.6 g/L.
